(19) United States
(12) Patent Application Publication
(10) Pub. No.: US 2025/0167018 A1
(43) Pub. Date: May 22, 2025

(54) SUBSTRATE PROCESSING APPARATUS AND SUBSTRATE PROCESSING METHOD

(71) Applicant: Tokyo Electron Limited, Tokyo (JP)

(72) Inventor: Manabu HONMA, Oshu City (JP)

(21) Appl. No.: 18/945,702

(22) Filed: Nov. 13, 2024

(30) Foreign Application Priority Data
Nov. 22, 2023 (JP) 2023-197964

(51) Int. Cl. H01L 21/67; H01L 21/677

(52) U.S. Cl. CPC H01L 21/67201; H01L 21/67754; H01L 21/67757

(57) ABSTRACT

A substrate processing apparatus includes a first processing chamber configured to collectively perform first processing on a plurality of substrates held by a substrate holder in a shelf-like shape, a load lock chamber located below the first processing chamber and having an interior communicating with an inside of the first processing chamber, and a driving mechanism configured to move the substrate holder up and down and horizontally.

### CROSS-REFERENCE TO RELATED APPLICATION

This application is based upon and claims the benefit of priority from Japanese Patent Application No. 2023-197964, filed on Nov. 22, 2023, the entire contents of which are incorporated herein by reference.

### TECHNICAL FIELD

The present disclosure relates to a substrate processing apparatus and a substrate processing method.

### BACKGROUND

An apparatus is known that loads a substrate holder equipped with a plurality of substrates into a processing container and performs processing on the substrates collectively (see, for example, Patent Document 1). For example, the substrate holder is loaded into the processing container by a boat elevator.

### Prior Art Document

Patent Document
Patent Document 1: Japanese Patent Laid-Open Publication No. 1993-226267

### SUMMARY

According to one embodiment of the present disclosure, there is provided a substrate processing apparatus, including: a first processing chamber configured to collectively perform first processing on a plurality of substrates held by a substrate holder in a shelf-like shape; a load lock chamber located below the first processing chamber and having an interior communicating with an inside of the first processing chamber; and a driving mechanism configured to move the substrate holder up and down and horizontally.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal cross-sectional view showing a substrate processing apparatus according to a first embodiment.

FIG. 2 is a longitudinal cross-sectional view showing the substrate processing apparatus according to the first embodiment.

FIG. 3 is a longitudinal cross-sectional view showing the substrate processing apparatus according to the first embodiment.

FIG. 4 is a longitudinal cross-sectional view showing the substrate processing apparatus according to the first embodiment.

FIG. 5 is a longitudinal cross-sectional view showing a substrate processing apparatus according to a second embodiment.

FIG. 6 is a longitudinal cross-sectional view showing the substrate processing apparatus according to the second embodiment.

FIG. 7 is a longitudinal cross-sectional view showing the substrate processing apparatus according to the second embodiment.

FIG. 8 is a longitudinal cross-sectional view showing the substrate processing apparatus according to the second embodiment.

FIG. 9 is a longitudinal cross-sectional view showing a substrate processing apparatus according to a third embodiment.

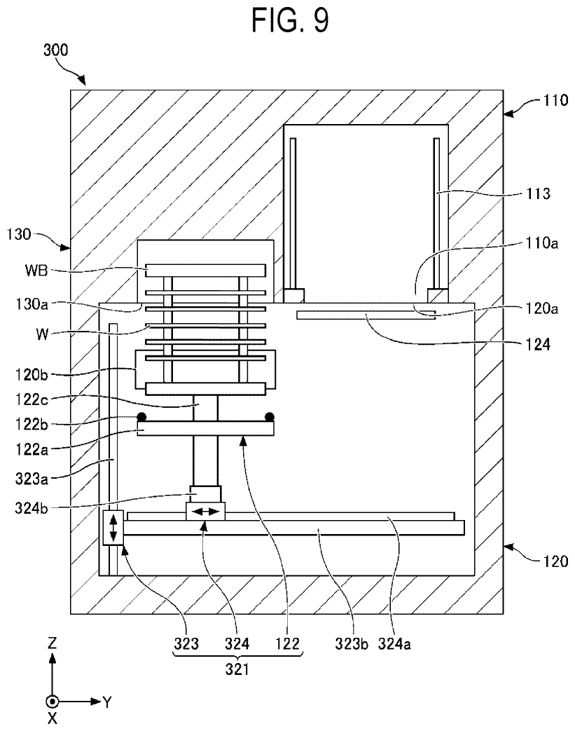

FIG. 10 is a side view showing a substrate processing apparatus according to a fourth embodiment.

FIG. 11 is a longitudinal cross-sectional view showing the substrate processing apparatus according to the fourth embodiment.

FIG. 12 is a longitudinal cross-sectional view showing the substrate processing apparatus according to the fourth embodiment.

FIG. 13 is a longitudinal cross-sectional view showing the substrate processing apparatus according to the fourth embodiment.

FIG. 14 is a transverse cross-sectional view showing the substrate processing apparatus according to the fourth embodiment.

FIG. 15 is a transverse cross-sectional view showing the substrate processing apparatus according to the fourth embodiment.

FIG. 16 is a plan view showing a substrate processing apparatus according to a fifth embodiment.

FIG. 17 is a cross-sectional view taken along line II-II in FIG. 16 when viewed in an arrow direction.

FIGS. 18A and 18B are cross-sectional views taken along line III-III in FIG. 16 when viewed in an arrow direction.

FIG. 19 is a cross-sectional view taken along line IV-IV in FIG. 16 when viewed in an arrow direction.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limitative exemplary embodiments of the present disclosure will be described with reference to the accompanying drawings. In all the attached drawings, the same or corresponding members or components will be denoted by the same or corresponding reference numerals, and redundant descriptions thereof will be omitted.

### First Embodiment

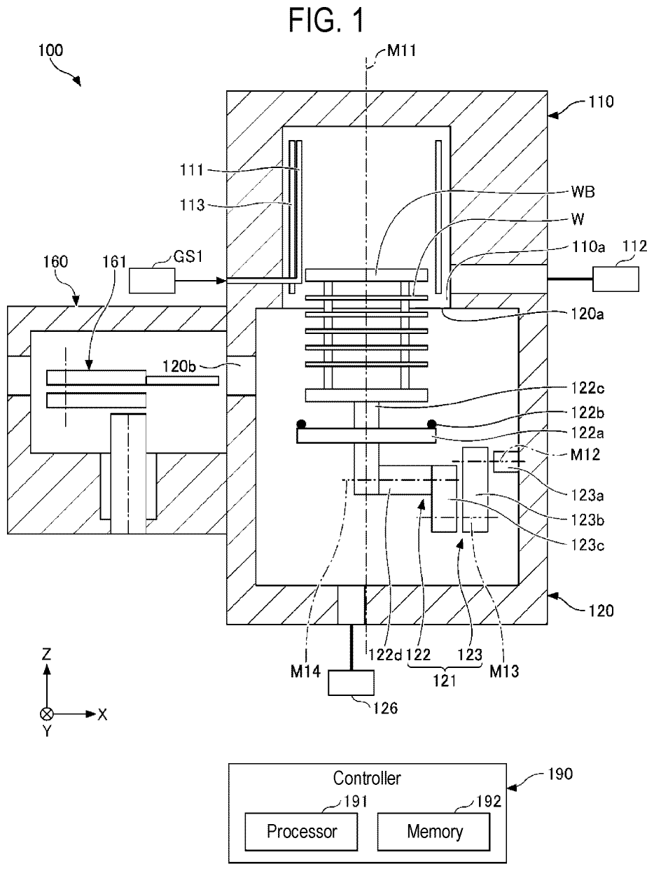

A substrate processing apparatus 100 according to a first embodiment will now be described with reference to FIGS. 1 to 4. The substrate processing apparatus 100 includes a processing chamber 110, a load lock chamber 120, a transfer dedicated chamber 130, a substrate transfer chamber 160, and a controller 190.

The interior of the processing chamber 110 is capable of being depressurized. The processing chamber 110 is capable of accommodating a substrate holder WB therein. The substrate holder WB holds a plurality of substrates W in a shelf-like shape. While five substrates are shown in FIGS. 1 to 4, the number of substrates W is not limited thereto. In the processing chamber 110, processing is collectively performed on the plurality of substrates W held by the substrate holder WB. A loading/unloading port 110a for loading and unloading the substrate holder WB is provided at a lower portion of the processing chamber 110. The processing chamber 110 is provided with a gas nozzle 111, an exhaust device 112, and a heater 113.

The gas nozzle 111 is provided around the substrate holder WB located in the processing chamber 110. The gas nozzle 111 ejects a process gas generated from a gas source GS1 toward the substrate holder WB and the substrates W from the periphery of the substrate holder WB located in the processing chamber 110. The process gas is selected according to a processing type. The number of gas nozzles 111 may be one, or two or more.

The exhaust device 112 depressurizes the inside of the processing chamber 110 by exhausting the interior of the processing chamber 110. The exhaust device 112 includes, for example, a vacuum pump and a pressure regulating valve. The exhaust device 112 controls the interior of the processing chamber 110 to a desired pressure by adjusting the opening degree of the pressure regulating valve while vacuumizing the interior of the processing chamber 110 using the vacuum pump.

The heater 113 is provided in the processing chamber 110. The heater 113 may be provided around the substrate holder WB located in the processing chamber 110. The heater 113 heats the substrate holder WB and the substrates W to a desired temperature from the periphery of the substrate holder WB located in the processing chamber 110.

The load lock chamber 120 is located below the processing chamber 110. The interior of the load lock chamber 120 is capable of being depressurized. The load lock chamber 120 is capable of accommodating the substrate holder WB therein. A loading/unloading port 120a for loading and unloading the substrate holder WB is provided at an upper portion of the load lock chamber 120. The interior of the load lock chamber 120 communicates with the interior of the processing chamber 110 via the loading/unloading port 110a and the loading/unloading port 120a. The substrate holder WB is loaded from the interior of the load lock chamber 120 into the processing chamber 110 via the loading/unloading port 110a and the loading/unloading port 120a. The substrate holder WB is unloaded from the interior of the processing chamber 110 into the load lock chamber 120 via the loading/unloading port 110a and the loading/unloading port 120a. In the load lock chamber 120, the substrates W are loaded to the substrate holder WB and unloaded from the substrate holder WB. A loading/unloading port 120b for loading and unloading the substrates W is provided on a side wall of the negative side of the load lock chamber 120 in the X-axis direction. The substrates W are loaded from the interior of the substrate transfer chamber 160 into the load lock chamber 120 through the loading/unloading port 120b. The substrates W are unloaded from the interior of the load lock chamber 120 into the substrate transfer chamber 160 through the loading/unloading port 120b. The load lock chamber 120 is provided with a driving mechanism 121, a shutter 124, and an exhaust device 126.

The driving mechanism 121 is configured to move the substrate holder WB up and down and horizontally. The driving mechanism 121 is configured to move the substrate holder WB up and down between the interior of the processing chamber 110 and the interior of the load lock chamber 120. The driving mechanism 121 is configured to move the substrate holder WB horizontally inside the load lock chamber 120. The driving mechanism 121 may be configured to move the substrate holder WB horizontally inside the processing chamber 110. The driving mechanism 121 has a support 122 and an articulated arm 123.

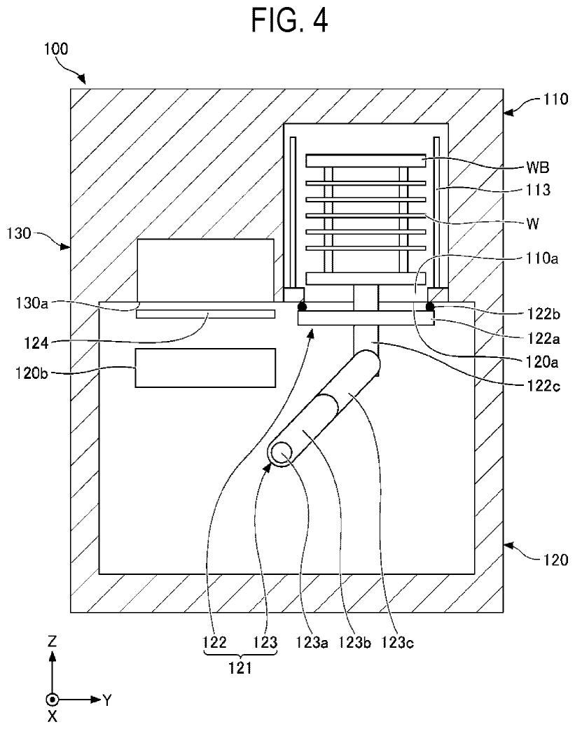

The support 122 supports the substrate holder WB. The support 122 has a cover 122a, a seal member 122b, a rotating shaft 122c, and a supporting arm 122d. When the substrate holder WB is positioned in the processing chamber 110 (FIG. 4), the cover 122a hermetically seals the loading/unloading port 110a and the loading/unloading port 120a using the seal member 122b. Thereby, the interior of the processing chamber 110 is hermetically sealed. The seal member 122b is, for example, an O-ring. A through hole that passes through the cover 122a vertically is provided in the center of the cover 122a. The rotating shaft 122c is inserted into the through hole. A gap between the cover 122a and the rotating shaft 122c is sealed by a magnetic fluid seal. The rotating shaft 122c rotatably supports the substrate holder WB around a vertical axis M11. The supporting arm 122d is connected to a lower portion of the rotating shaft 122c. The supporting arm 122d supports the rotating shaft 122c.

The articulated arm 123 may be a vertical articulated arm. In this case, torque is always applied to a joint, so gear backlash is cancelled and positioning accuracy is improved. A base end of the articulated arm 123 is fixed to a side wall of the positive side of the load lock chamber 120 in the X-axis direction, and a tip end thereof is connected to the supporting arm 122d. The articulated arm 123 moves the support 122 up and down and horizontally by rotating around the base end as the center of rotation.

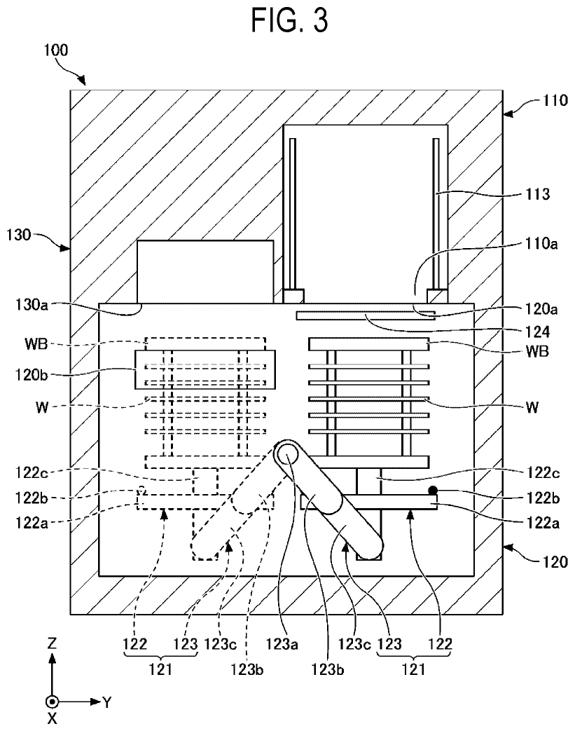

The articulated arm 123 moves the substrate holder WB up and down between a processing position and an unloading position by moving the support 122 up and down. The processing position may be a position at which the entirety of the substrate holder WB is accommodated in the processing chamber 110 and the cover 122a hermitically closes the loading/unloading port 110a and the loading/unloading port 120a as shown in FIG. 4. The unloading position may be a position directly below the processing position as shown in FIG. 3 and a position at which the entirety of the substrate holder WB is accommodated in the load lock chamber 120 (see the substrate holder WB shown by a solid line in FIG. 3). The articulated arm 123 raises the support 122 to load the substrate holder WB from the unloading position to the processing position. The articulated arm 123 lowers the support 122 to unload the substrate holder WB from the processing position to the unloading position. The articulated arm 123 may move the substrate holder WB horizontally inside the processing chamber 110 by moving the support 122 horizontally.

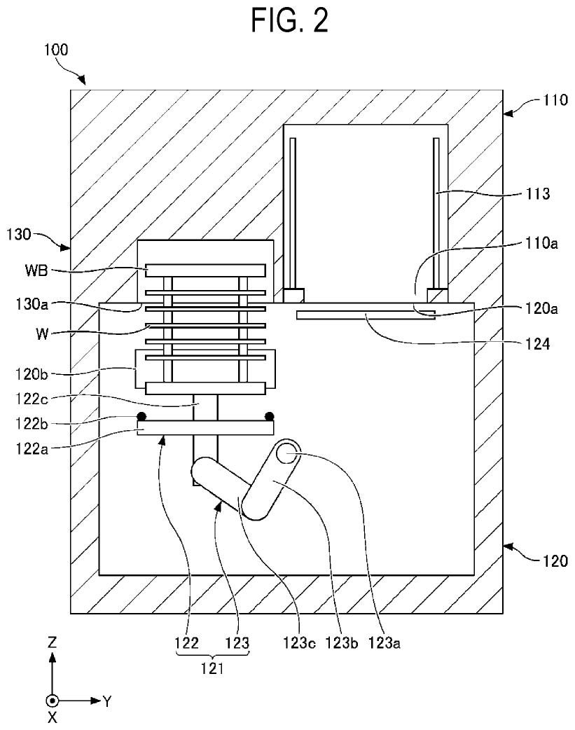

The articulated arm 123 moves the substrate holder WB horizontally between the unloading position and a transfer position by moving the support 122 horizontally. The transfer position is different from the unloading position in a horizontal direction. The transfer position may be a position at which a part of the substrate holder WB faces the loading/unloading port 120b as shown in FIGS. 2 and 3. The transfer position may include a plurality of different positions in a vertical direction. The plurality of positions includes a first position and a second position. The first position is a position at which most of the substrate holder WB is in the load lock chamber 120 and an upper portion of the substrate holder WB is in the transfer dedicated chamber 130 (FIG. 2). The second position is a position at which the entirety of the substrate holder WB is located in the load lock chamber 120 (see the substrate holder WB indicated by a dashed line in FIG. 3). The articulated arm 123 may move the substrate holder WB up and down between the first position and the second position which are included in the transfer position by moving the support 122 up and down.

The articulated arm 123 may include therein a refrigerant passage through which a refrigerant flows. In this case, since heat of the articulated arm 123 can be removed even in a vacuum atmosphere, positioning accuracy can be maintained.

The articulated arm 123 includes a base end 123a, a first arm 123b, and a second arm 123c.

The base end 123a is fixed to the side wall of the positive side of the load lock chamber 120 in the X-axis direction. The first arm 123b is rotatable about the base end 123a centering around a rotation axis M12. The second arm 123c is rotatable about the first arm 123b centering around a rotation axis M13 and is rotatable about the supporting arm 122d centering around a rotation axis M14. The articulated arm 123 moves the substrate holder WB between a plurality of positions including the processing position, the unloading position, and the transfer position by independently rotating the first arm 123b and the second arm 123c.

The shutter 124 is configured to be movable horizontally in a Y-axis direction between a position at which the loading/unloading port 110a and the loading/unloading port 120a are sealed and a position at which an opening 130a is sealed. When the substrate holder WB is outside the processing chamber 110, as shown in, for example, FIGS. 2 and 3, the shutter 124 moves to the position at which the loading/unloading port 110a and the loading/unloading port 120a are sealed to hermetically seal the loading/unloading port 110a and the loading/unloading port 120a. When the substrate holder WB is inside the processing chamber 110, as shown in, for example, FIG. 4, the shutter 124 moves to the position at which the opening 130a is sealed to hermitically seal the opening 130a.

The exhaust device 126 depressurizes the interior the load lock chamber 120 by exhausting the interior of the load lock chamber 120. The exhaust device 126 includes, for example, a vacuum pump and a pressure regulating valve. The exhaust device 126 controls pressure inside the load lock chamber 120 to a desired pressure by adjusting the opening degree of the pressure control valve while vacuumizing the interior of the load lock chamber 120 using the vacuum pump.

The transfer dedicated chamber 130 is located above the load lock chamber 120 and has an interior communicating with the interior of the load lock chamber 120. The transfer dedicated chamber 130 is located at a lateral side of the processing chamber 110. The transfer dedicated chamber 130 may be located on the negative side of the processing chamber 110 in the Y-axis direction. The opening 130a for allowing the substrate holder WB to pass therethrough is provided at a lower portion of the transfer dedicated chamber 130. The transfer dedicated chamber 130 is configured to be capable of accommodating a part of the substrate holder WB therein. For example, as shown in FIG. 2, when the substrates W are loaded or unloaded through the loading/unloading port 120b to or from a lower portion of the substrate holder WB in the transfer position, the transfer dedicated chamber 130 accommodates an upper portion of the substrate holder WB. Thereby, the substrate holder WB can be prevented from contacting the ceiling of the load lock chamber 120.

The substrate transfer chamber 160 is connected to the negative side of the load lock chamber 120 in the X-axis direction. The interior of the substrate transfer chamber 160 is capable of being depressurized. The substrate transfer chamber 160 is provided with a substrate transfer robot 161. The substrate transfer chamber 160 may be provided with an exhaust device.

The substrate transfer robot 161 is provided inside the substrate transfer chamber 160. The substrate transfer robot 161 loads the substrate W to the substrate holder WB located at the transfer position via the loading/unloading port 120b and unloads the substrate W held by the substrate holder WB located at the transfer position via the loading/unloading port 120b. The substrate transfer robot 161 may include a horizontal articulated arm.

The controller 190 may be realized as a computer having one or more processors 191, a memory 192, an input/output interface (not shown), and an electronic circuit. The processor 191 is a combination of one or more of a central processing unit (CPU), an application specific integrated circuit (ASIC), a field programmable gate array (FPGA), and a circuit made of a plurality of discrete semiconductors. The memory 192 includes a non-transitory computer readable volatile memory or a non-volatile memory (e.g., a compact disc, a DVD, a hard disk, a flash memory, etc.) and stores a program for operating the substrate processing apparatus 100 and a recipe such as processing conditions for processing. The processor 191 executes the program and recipe stored in the memory 192 to control each component of the substrate processing apparatus 100 and perform various processes.

As described above, according to the first embodiment, the substrate processing apparatus 100 includes the processing chamber 110, the load lock chamber 120, and the driving mechanism 121. In the processing chamber 110, processing is collectively performed on the plurality of substrates W held by the substrate holder WB in a shelf-like shape. The load lock chamber 120 is located below the processing chamber 110 and has an interior communicating with the interior of the processing chamber 110. The driving mechanism 121 moves the substrate holder WB up and down and horizontally. In this case, the substrate W can be loaded and unloaded to and from the substrate holder WB in a state in which the entirety of the substrate holder WB is unloaded from the processing chamber 110. This makes it possible to reduce the difference in thermal history between the substrates W held by the substrate holder WB. In addition, by moving the substrate holder WB horizontally inside the processing chamber 110, the thickness distribution of a film formed on the substrates W is adjustable.

While, in the first embodiment, a description of the articulated arm 123 having two arms (the first arm 123b and the second arm 123c) has been given, the number of arms constituting the articulated arm 123 is not limited thereto. The articulated arm 123 may have three or more arms.

### Second Embodiment

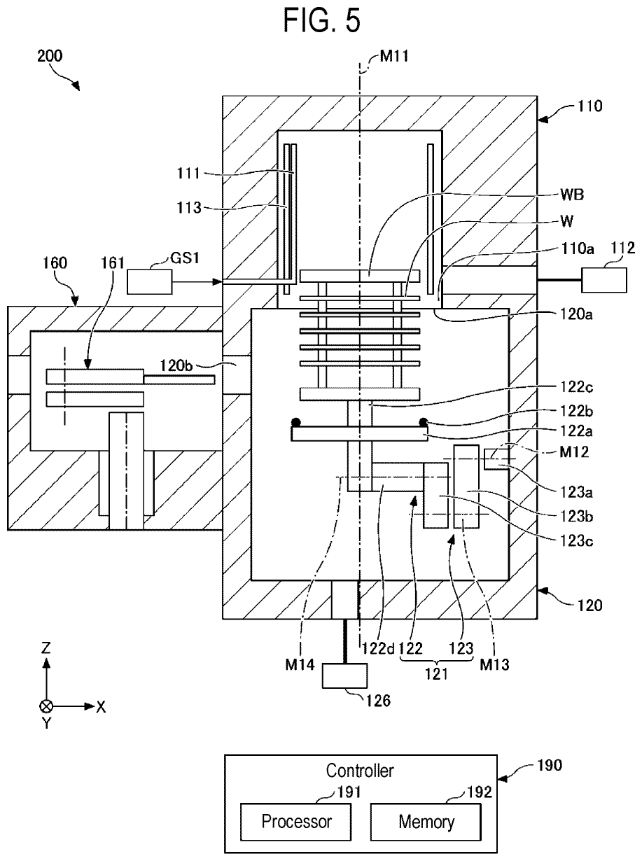

A substrate processing apparatus 200 according to a second embodiment will now be described with reference to FIGS. 5 to 8. The substrate processing apparatus 200 differs from the substrate processing apparatus 100 in that a second processing chamber 230 is provided instead of the transfer dedicated chamber 130. The following description will be given focusing on differences from the substrate processing apparatus 100.

The substrate processing apparatus 200 includes the processing chamber 110, the load lock chamber 120, the second processing chamber 230, the substrate transfer chamber 160, and the controller 190.

The second processing chamber 230 is located above the load lock chamber 120 and has an interior communicating with the interior of the load lock chamber 120. The second processing chamber 230 is located at a lateral side of the processing chamber 110. The second processing chamber 230 may be located on the negative side of the processing chamber 110 in the Y-axis direction. The interior of the second processing chamber 230 is capable of being depressurized. A loading/unloading port 230a for loading and unloading the substrate holder WB is provided at a lower portion of the second processing chamber 230. The second processing chamber 230 is configured to be capable of accommodating the entirety of the substrate holder WB therein.

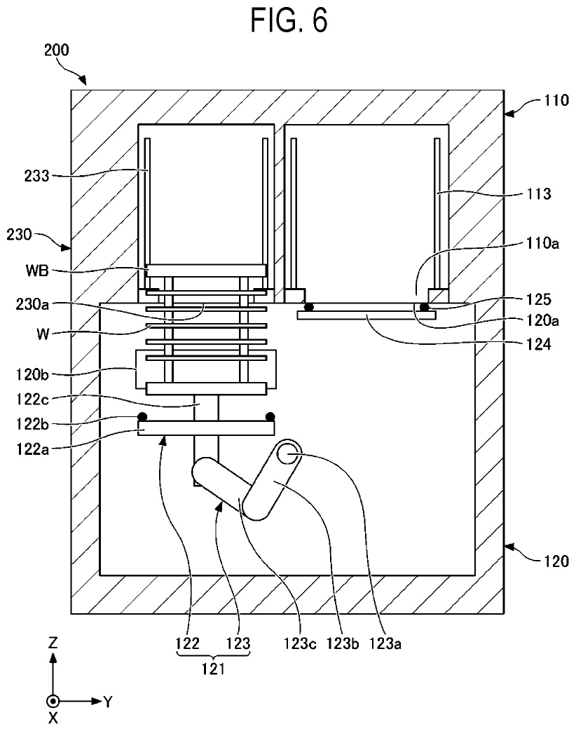

For example, as shown in FIG. 6, when the substrates W are loaded or unloaded via the loading/unloading port 120b to or from a lower portion of the substrate holder WB located at the transfer position, the second processing chamber 230 accommodates an upper portion of the substrate holder WB. Thereby, the substrate holder WB can be prevented from contacting the ceiling of the load lock chamber 120.

In the second processing chamber 230, processing is collectively performed on the plurality of substrates W held by the substrate holder WB. In this case, the entirety of the substrate holder WB is accommodated inside the second processing chamber 230. The processing performed in the second processing chamber 230 may be different from the processing performed in the processing chamber 110. The processing performed in the processing chamber 110 may include a film forming process. The processing performed in the second processing chamber 230 may include an annealing process and a pre-cleaning process.

The second processing chamber 230 is provided with a heater 233. The second processing chamber 230 may be provided with a gas nozzle, an exhaust device, etc.

The heater 233 is provided in the second processing chamber 230. The heater 233 may be provided around the substrate holder WB located in the second processing chamber 230. The heater 233 heats the substrate holder WB and the substrates W to a desired temperature from the periphery of the substrate holder WB located in the second processing chamber 230.

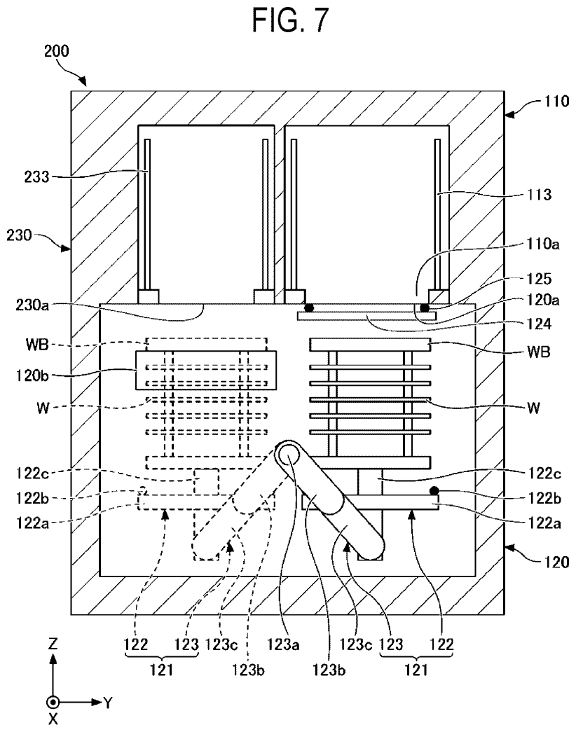

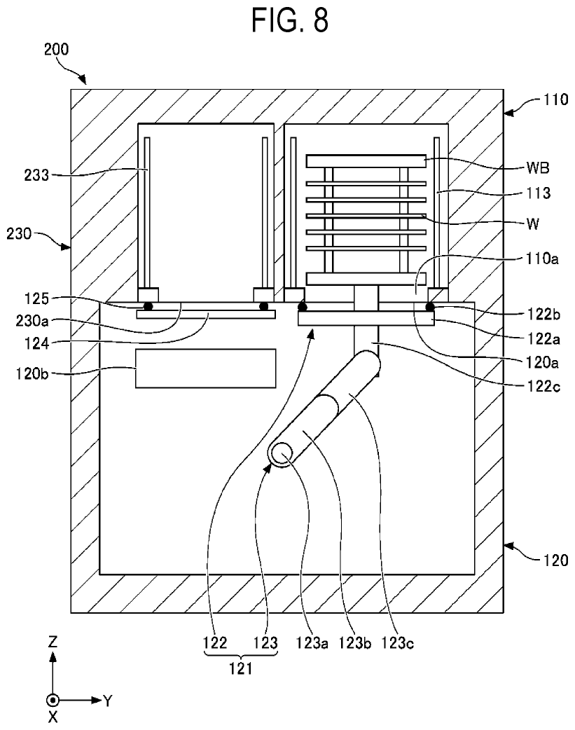

The articulated arm 123 moves the substrate holder WB up and down between the processing position and the unloading position by moving the support 122 up and down. The processing position may be a position at which the entirety of the substrate holder WB is accommodated in the processing chamber 110 and the cover 122a hermetically seals the loading/unloading port 110a and the loading/unloading port 120a as shown in FIG. 8. The unloading position may be a position directly below the processing position as shown in FIG. 7 and a position at which the entirety of the substrate holder WB is accommodated in the load lock chamber 120 (see the substrate holder WB shown by a solid line in FIG. 7). The articulated arm 123 loads the substrate holder WB from the unloading position to the processing position by raising the support 122. The articulated arm 123 unloads the substrate holder WB from the processing position to the unloading position by lowering the support 122. The articulated arm 123 may move the substrate holder WB horizontally inside the processing chamber 110 by moving the support 122 horizontally.

The articulated arm 123 moves the substrate holder WB horizontally between the unloading position and the transfer position by moving the support 122 horizontally. The transfer position is different from the unloading position in a horizontal direction. The transfer position may be a position at which a part of the substrate holder WB faces the loading/unloading port 120b as shown in FIGS. 6 and 7. The transfer position may include a plurality of different positions in a vertical direction. The plurality of positions includes a first position and a second position. The first position is a position at which most of the substrate holder WB is in the load lock chamber 120 and an upper portion of the substrate holder WB is in the transfer dedicated chamber 130 (FIG. 6). The second position is a position at which the entirety of the substrate holder WB is located in the load lock chamber 120 (see the substrate holder WB indicated by a dashed line in FIG. 7). The articulated arm 123 may move the substrate holder WB up and down between the first position and the second position which are included in the transfer position by moving the support 122 up and down.

The articulated arm 123 moves the substrate holder WB up and down between the transfer position and a second processing position by moving the support 122 up and down. The second processing position may be a position immediately above the transfer position and a position at which the entirety of the substrate holder WB is accommodated in the second processing chamber 230. The articulated arm 123 loads the substrate holder WB from the transfer position to the second processing position by raising the support 122. The articulated arm 123 unloads the substrate holder WB from the second processing position to the transfer position by lowering the support 122. The articulated arm 123 may move the substrate holder WB horizontally inside the second processing chamber 230 by moving the support 122 horizontally.

The shutter 124 is configured to be movable horizontally in a Y-axis direction between a position at which the loading/unloading port 110a and the loading/unloading port 120a are sealed and a position at which a loading/unloading port 230a is sealed. When the substrate holder WB is outside the processing chamber 110, as shown in, for example, FIGS. 6 and 7, the shutter 124 moves to the position at which the loading/unloading port 110a and the loading/unloading port 120a are sealed to hermetically seal the loading/unloading port 110a and the loading/unloading port 120a using the seal member 125. When the substrate holder WB is inside the processing chamber 110, as shown in, for example, FIG. 8, the shutter 124 moves to the position at which the loading/unloading port 230a is sealed to hermetically seal the loading/unloading port using the seal member 125. The seal member 125 is, for example, an O-ring.

As described above, according to the second embodiment, the substrate processing apparatus 200 includes the processing chamber 110, the load lock chamber 120, and the driving mechanism 121. In the processing chamber 110, processing is collectively performed on the plurality of substrates W held by the substrate holder WB in a shelf-like shape. The load lock chamber 120 is located below the processing chamber 110 and has an interior communicating with the interior of the processing chamber 110. The driving mechanism 121 moves the substrate holder WB up and down and horizontally. In this case, the same effect as in the first embodiment is obtained.

According to the second embodiment, the substrate processing apparatus 200 includes the second processing chamber 230. In this case, different processing can be performed on the substrates W held by the substrate holder WB without replacing the substrates W.

### Third Embodiment

A substrate processing apparatus 300 according to a third embodiment will now be described with reference to FIG, 9. The substrate processing apparatus 300 differs from the substrate processing apparatus 100 in that the substrate processing apparatus 300 includes a driving mechanism 321 having an elevation driving mechanism 323 and a horizontal driving mechanism 324, instead of the driving mechanism 121 having the articulated arm 123. The following description will be given focusing on configurations different from those of the substrate processing apparatus 100.

The driving mechanism 321 includes the support 122, the elevation driving mechanism 323, and the horizontal driving mechanism 324.

The elevation driving mechanism 323 includes a guide rail 323a and a supporting arm 323b. The guide rail 323a has a lower end fixed to a bottom wall of the load lock chamber 120 and extends vertically. The supporting arm 323b moves up and down along the guide rail 323a. The elevation driving mechanism 323 may include a boat elevator.

The horizontal driving mechanism 324 includes a guide rail 324a and a support 324b. The guide rail 324a is fixed to the supporting arm 323b and extends in the Y-axis direction. The support 324b moves horizontally in the Y-axis direction along the guide rail 324a. The support 324b supports the support 122. The horizontal driving mechanism 324 may include a ball screw.

The driving mechanism 321 moves the substrate holder WB between a plurality of positions including a processing position, an unloading position, and a transfer position by moving the horizontal driving mechanism 324 up and down using the elevation driving mechanism 323 and also moving the support 122 horizontally using the horizontal driving mechanism 324.

As described above, according to the third embodiment, the substrate processing apparatus 300 includes the processing chamber 110, the load lock chamber 120, and the driving mechanism 321. In the processing chamber 110, processing is collectively performed on the plurality of substrates W held by the substrate holder WB in a shelf-like shape. The load lock chamber 120 is located below the processing chamber 110 and has an interior communicating with the interior of the processing chamber 110. The driving mechanism 321 moves the substrate holder WB up and down and horizontally. In this case, the same effect as in the first embodiment is obtained.

### Fourth Embodiment

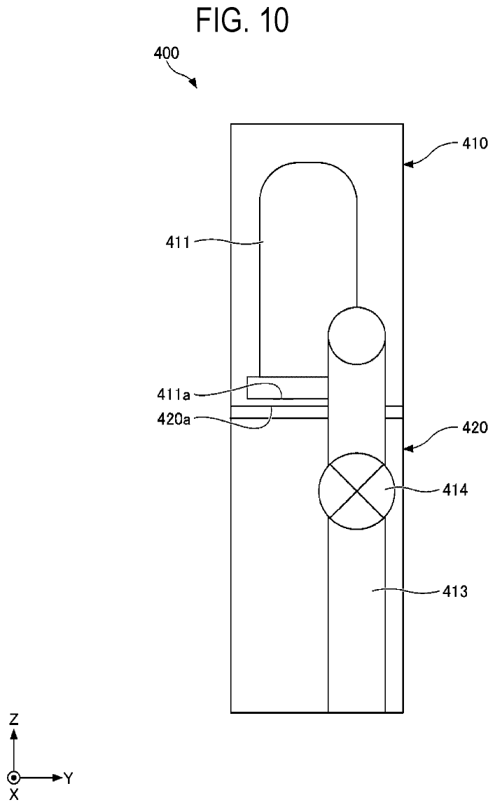

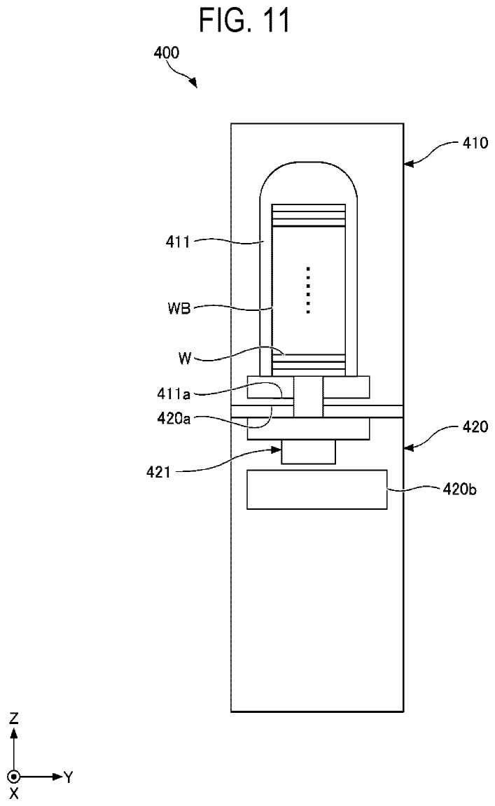

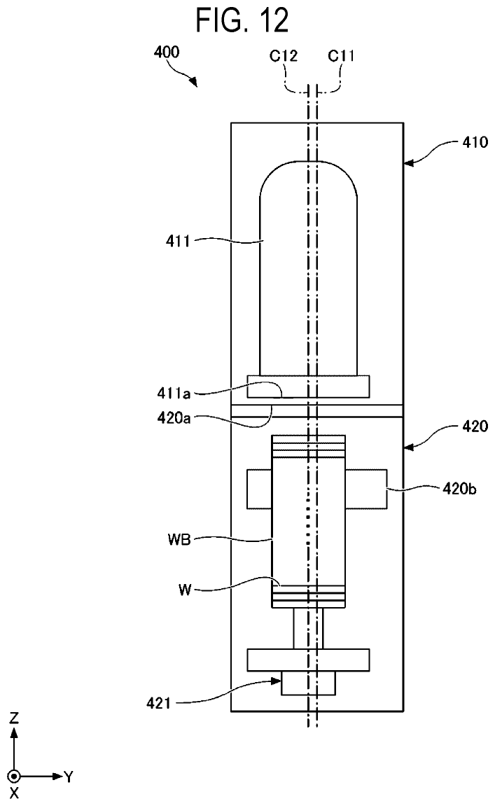

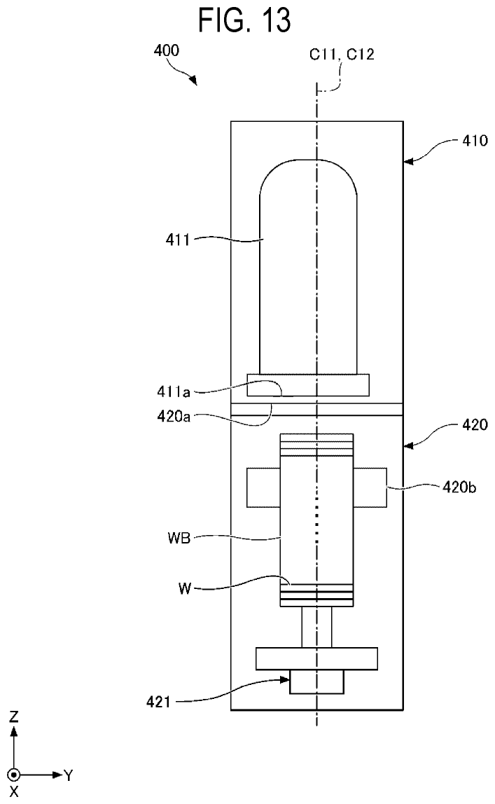

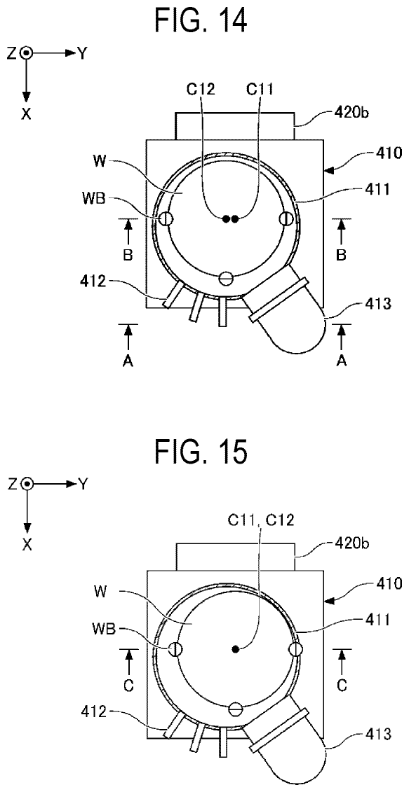

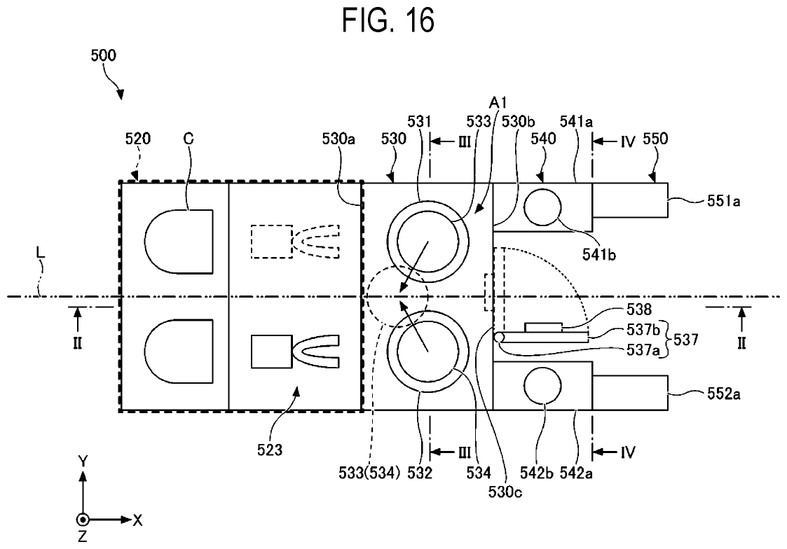

A substrate processing apparatus 400 according to a fourth embodiment will now be described with reference to FIGS. 10 to 15. FIG. 10 is a side view showing the substrate processing apparatus 400 according to the fourth embodiment. FIGS. 11 to 13 are longitudinal cross-sectional views showing the substrate processing apparatus 400 according to the fourth embodiment. FIGS. 14 and 15 are transverse cross-sectional views showing the substrate processing apparatus 400 according to the fourth embodiment. FIG. 10 is a side view taken along line A-A in FIG. 14 when viewed in an arrow direction. FIGS. 11 and 12 are cross-sectional views taken along arrow line B-B in FIG. 14 when viewed in an arrow direction. FIG. 13 is a cross-sectional view taken along line C-C in FIG. 15 when viewed in an arrow direction.

The substrate processing apparatus 400 includes a processing chamber 410 and a load lock chamber 420.

The processing chamber 410 is provided with a reaction tube 411, a gas nozzle 412, and an exhaust pipe 413.

The interior of the reaction tube 411 is capable of being depressurized. The reaction tube 411 is capable of accommodating the substrate holder WB therein. The substrate holder WB holds a plurality of substrates W in a shelf-like shape. In the reaction tube 411, processing is collectively performed on the plurality of substrates W held by the substrate holder WB. A loading/unloading port 411a for loading and unloading the substrate holder WB is provided at a lower portion of the reaction tube 411.

The gas nozzle 412 ejects a process gas into the reaction tube 411. The process gas is selected according to a processing type. The number of gas nozzles 412 may be one, or two or more.

The exhaust pipe 413 has one end connected to the reaction tube 411 and the other end connected to a vacuum pump (not shown). The vacuum pump depressurizes the interior of the reaction tube 411 by exhausting the interior of the reaction tube 411 via the exhaust pipe 413. The exhaust pipe 413 is provided with a valve 414. The valve 414 controls exhaust conductance by adjusting the opening degree thereof.

The load lock chamber 420 is located below the processing chamber 410. The interior of the load lock chamber 420 is capable of being depressurized. The load lock chamber 420 is capable of accommodating the substrate holder WB therein. A loading/unloading port 420a for loading and unloading the substrate holder WB is provided at an upper portion of the load lock chamber 420. The interior of the load lock chamber 420 communicates with the interior of the reaction tube 411 via the loading/unloading port 411a and the loading/unloading port 420a. The substrate holder WB is loaded from the interior of the load lock chamber 420 into the reaction tube 411 via the loading/unloading port 411a and the loading/unloading port 420a. The substrate holder WB is unloaded from the interior of the reaction tube 411 into the load lock chamber 420 via the loading/unloading port 411a and the loading/unloading port 420a. In the load lock chamber 420, the substrates W are loaded to the substrate holder WB and unloaded from the substrate holder WB. A loading/unloading port 420b for loading and unloading the substrates W is provided on a side wall of the negative side of the load lock chamber 420 in the X-axis direction. The substrates W are loaded from the interior of a substrate transfer chamber (not shown) into the load lock chamber 420 through the loading/unloading port 420b. The substrates W are unloaded from the interior of the load lock chamber 420 into the substrate transfer chamber through the loading/unloading port 420b. The load lock chamber 420 is provided with a driving mechanism 421.

The driving mechanism 421 moves the substrate holder WB up and down and in a horizontal direction. The driving mechanism 421 is configured to move the substrate holder WB up and down between the interior of the reaction tube 411 and the interior of the load lock chamber 420. The driving mechanism 421 is configured to move the substrate holder WB horizontally inside the load lock chamber 420. The driving mechanism 421 may be configured to move the substrate holder WB horizontally inside the reaction tube 411.

The driving mechanism 421 moves the substrate holder WB up and down between a processing position and an unloading position. The processing position may be a position at which the entirety of the substrate holder WB is accommodated in the reaction tube 411 as shown in FIG. 11. The unloading position may be a position directly below the processing position as shown in FIG. 12 and may be a position at which a central axis C12 of the substrate holder WB is shifted to the negative side in the Y-axis direction with respect to a central axis C11 of the processing chamber 410 as shown in FIGS. 12 and 14. The unloading position may be a position at which the entirety of the substrate holder WB is accommodated in the load lock chamber 420 as shown in FIG. 12.

The driving mechanism 421 moves the substrate holder WB horizontally between the unloading position and a transfer position. The transfer position is different from the unloading position in a horizontal direction. The transfer position may be a position shifted to the positive side in the Y-axis direction with respect to the unloading position as shown in FIG. 13. The transfer position may be a position at which the central axis C12 of the substrate holder WB coincides with the central axis C11 of the processing chamber 410 as shown in FIGS. 13 and 15.

As described above, according to the fourth embodiment, the substrate processing apparatus 400 includes the processing chamber 410, the load lock chamber 420, and the driving mechanism 421. In the processing chamber 410, processing is collectively performed on a plurality of substrates W held by the substrate holder WB in a shelf-like shape. The load lock chamber 420 is located below the processing chamber 410 and has an interior communicating with the interior of the processing chamber 410. The driving mechanism 421 moves the substrate holder WB up and down and horizontally. In this case, the same effect as in the first embodiment is obtained.

According to the fourth embodiment, the central axis C12 of the substrate holder WB can be arranged so as to be shifted in a horizontal direction with respect to the central axis C11 of the processing chamber 410. In this case, the degree of freedom of layout, such as a position at which the gas nozzle 412 is provided and a position at which the exhaust pipe 413 is provided, is improved. In addition, the degree of freedom of layout of an installation position when a plasma generation unit is installed in the reaction tube 411 is improved. For example, when the exhaust pipe 413 is made larger in diameter, as shown in FIG. 10, the exhaust pipe 413 may be installed outside an outer end of the reaction tube 411 in the Y-axis direction. In this case, the reaction tube 411 and the exhaust pipe 413 can be arranged without increasing the width of the processing chamber 410 in the Y-axis direction by shifting the center axis C12 of the substrate holder WB to the negative side in the Y-axis direction with respect to the center axis C11 of the processing chamber 410.

### Fifth Embodiment

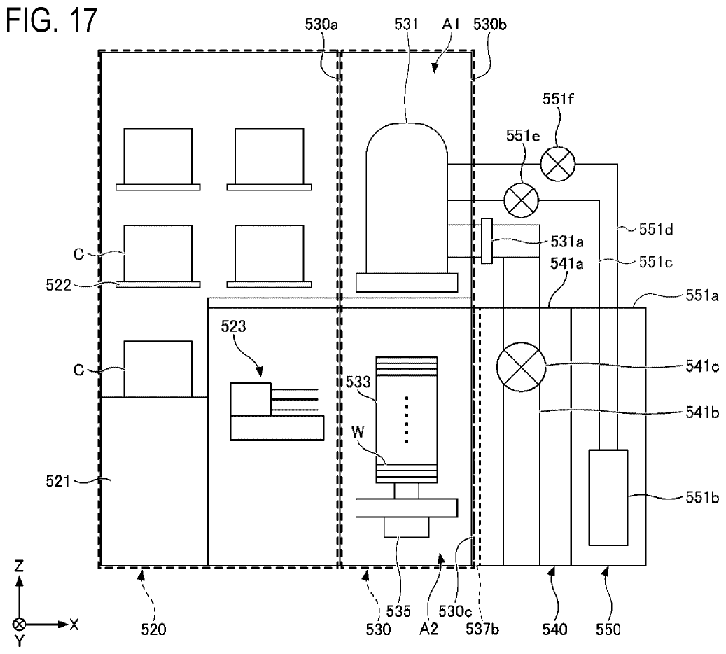

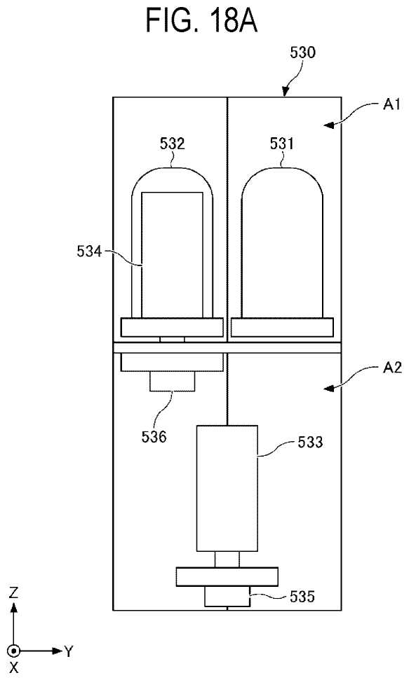

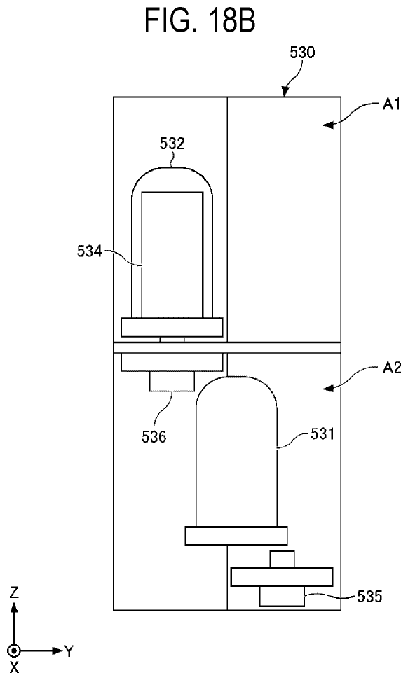

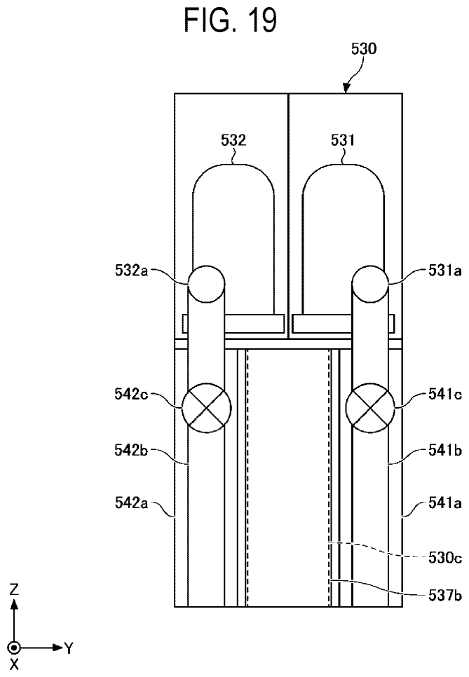

A substrate processing apparatus 500 according to a fifth embodiment will now be described with reference to FIGS. 16 to 19. FIG. 16 is a plan view showing the substrate processing apparatus 500 according to the fifth embodiment. FIG. 17 is a cross-sectional view taken along line II-II in FIG. 16 when viewed in an arrow direction. FIGS. 18A and 18B are cross-sectional views taken along the line III-III in FIG. 16 when viewed in an arrow direction. FIG. 18A shows a first boat 533 in a position when the first boat 533 is loaded/unloaded into/from a processing module 530. FIG. 18B shows a first processing container 531 in a position when the first processing container 531 is loaded/unloaded into/from the processing module 530. FIG. 19 is a cross-sectional view taken along line IV-IV in FIG. 16 when viewed in an arrow direction in FIG. 16.

The substrate processing apparatus 500 includes a transfer module 520, a processing module 530, an exhaust unit 540, and a gas supply unit 550.

The transfer module 520 is disposed adjacent to a first side wall 530a of the processing module 530. The transfer module 520 transfers a substrate W to the processing module 530. The transfer module 520 includes a load port 521, a stocker 522, and a substrate transfer device 523.

The load port 521 is disposed on the negative side of the transfer module 520 in the X-axis direction. Multiple load ports 521 (e.g., two load ports 521) are disposed in the Y-axis direction. However, the number of the load ports 521 is not particularly limited. A cassette C is placed on the load port 521. The cassette C accommodates multiple substrates W (e.g., 25 substrates W). The cassette C is loaded and unloaded to and from the load port 521. The cassette C holds the substrates W horizontally. The cassette C is, for example, a front opening unified pod (FOUP).

Multiple stockers 522 (e.g., two stokers) are arranged, in the Z-axis direction, on the negative side of the transfer module 520 in the X-axis direction. Multiple stockers 522 (e.g., two stokers) may be arranged, in the Z-axis direction, on the positive side of the transfer module 520 in the X-axis direction. The stockers 522 may be arranged in the Y-axis direction. However, the number of the stockers 522 is not particularly limited. Each of the stockers 522 temporarily stores the cassette C.

The substrate transfer device 523 transfers the substrates W between the cassette C placed on the load port 521, the first boat 533, and a second boat 534. The substrate transfer device 523 transfers, for example, the multiple substrates W simultaneously. For example, the substrate transfer device 523 takes the substrates W before processing out of the cassette C placed on the load port 521 and transfers the substrates W to the first boat 533 and the second boat 534. For example, the substrate transfer device 523 takes the substrates W after processing out of the first boat 533 and the second boat 534 and transfers the substrates W to the cassette C placed on the load port 521.

The transfer module 520 may have a cassette transfer device that transfers the cassette C between the load port 521 and the stocker 522. The transfer module 520 may have a loader for delivering the substrates between the transfer module 520 and the substrate transfer device 523, separately from the load port 521.

The processing module 530 has a processing chamber A1 and a load lock chamber A2. The processing chamber A1 and the load lock chamber A2 are adjacent to each other in the Z-axis direction. The load lock chamber A2 is located on the negative side of the processing chamber A1 in the Z-axis direction. The processing module 530 has a first side wall 530a and a second side wall 530b. The first side wall 530a is located on the negative side of the processing module 530 in the X-axis direction. The second side wall 530b is located on the positive side of the processing module 530 in the X-axis direction. The first side wall 530a and the second side wall 530b are spaced apart in the X-axis direction. The first side wall 530a and the second side wall 530b each extend from an end of the negative side of the processing module 530 in the Y-axis direction to an end of the positive side of the processing module 530 in the Y-axis direction. The first side wall 530a and the second side wall 530b each extend from a lower end of the load lock chamber A2 to an upper end of the processing chamber A1.

The processing module 530 includes a first processing container 531, a second processing container 532, a first boat 533, a second boat 534, a first driving mechanism 535, a second driving mechanism 536, a maintenance door 537, and a clean unit 538.

The first processing container 531 and the second processing container 532 are disposed in the processing chamber A1. The first processing container 531 and the second processing container 532 are disposed between the first side wall 530a and the second side wall 530b in the X-axis direction. The first processing container 531 and the second processing container 532 are disposed adjacent to each other in the Y-axis direction.

The first processing container 531 is heated by a heater (not shown). The first processing container 531 is configured to be capable of accommodating the first boat 533 holding the substrate W. A process gas is supplied from the gas supply unit 550 into the first processing container 531. The process gas is selected according to a processing type. The process gas supplied into the first processing container 531 is exhausted by the exhaust unit 540. Inside the first processing container 531, desired processing is performed on the substrates W held by the first boat 533 by the process gas supplied from the gas supply unit 550. The second processing container 532 may have the same configuration as the first processing container 531.

The first boat 533 holds the multiple substrates W in a shelf-like shape in the Z-axis direction. The first boat 533 is movable between a delivery position (position shown in FIG. 17), a processing position, and a loading/unloading position (position shown in FIG. 18A). The delivery position is a position on the negative side of the processing module 530 in the Z-axis direction and a position of the center of the processing module 530 in the Y-axis direction (see the first boat 533 shown by a dashed line in FIG. 16). The processing position is a position at which the first boat 533 is accommodated in the first processing container 531 and is a position above the delivery position. The loading/unloading position is a position on the negative side of the processing module 530 in the Z-axis direction and a position of the center of the processing module 530 in the Y-axis direction. The loading/unloading position may be a position shifted to the positive side in the X-axis direction from the delivery position. In this case, it is easy to load and unload the first boat 533 to and from the processing module 530.

For example, the first boat 533 moves to the delivery position when the substrates W are delivered between the first boat 533 and the substrate transfer device 523. For example, the first boat 533 moves to the processing position when desired processing is performed on the substrates W. For example, the first boat 533 moves to the loading/unloading position when the substrates W are unloaded from the processing module 530 for maintenance.

The second boat 534 holds the multiple substrates W in a shelf-like shape in the Z-axis direction. The second boat 534 is movable between the delivery position, the processing position (positions shown in FIGS. 18A and 18B), and the loading/unloading position. The delivery position is a position on the negative side of the processing module 530 in the Z-axis direction and a position of the center of the processing module 530 in the Y-axis direction (see the second boat 534 shown by a dashed line in FIG. 16). The delivery position may be the same as the delivery position of the first boat 533. In this case, a mechanism for moving the substrate transfer device 523 in the Y-axis direction is not required. Therefore, the length of the processing module 530 in the Y-axis direction can be shortened. In addition, the stroke of the substrate transfer device 523 can be shortened. Therefore, the time required for transferring the substrate W by the substrate transfer device 523 can be shortened. The processing position is a position at which the second boat 534 is accommodated in the second processing container 532 and is positioned above the delivery position. The loading/unloading position is a position of the negative side of the processing module 530 in the Z-axis direction and a position of the center of the processing module 530 in the Y-axis direction. The loading/unloading position may be a position of the positive side of the processing module 530 in the X-axis direction. In this case, it is easy to load and unload the second boat 534 to and from the processing module 530. The loading/unloading position of the second boat 534 may be the same as the loading/unloading position of the first boat 533.

For example, the second boat 534 moves to the delivery position when the substrates W are delivered between the second boat 534 and the substrate transfer device 523. For example, the second boat 534 moves to the processing position when desired processing is performed on the substrates W. For example, the second boat 534 moves to the loading/unloading position when the substrates W are unloaded from the processing module 530 for maintenance.

The first driving mechanism 535 is configured to move the first boat 533 up and down and horizontally. The first driving mechanism 535 is configured to move the first boat 533 at least between the delivery position and the processing position. The first driving mechanism 535 may include a boat elevator. The first driving mechanism 535 may include an articulated arm. The first driving mechanism 535 may include an elevation driving mechanism for moving the first boat 533 up and down and a horizontal driving mechanism for moving the first boat 533 horizontally. The first driving mechanism 535 may be configured to move the first boat 533 between the delivery position, the processing position, and the loading/unloading position.

The second driving mechanism 536 is configured to move the second boat 534 up and down and horizontally. The second driving mechanism 536 is configured to move the second boat 534 at least between the delivery position and the processing position. The second driving mechanism 536 may include a boat elevator. The second driving mechanism 536 may include an articulated arm. The second driving mechanism 536 may include an elevation driving mechanism for moving the second boat 534 up and down and a horizontal driving mechanism for moving the second boat 534 horizontally. The second driving mechanism 536 may be configured to move the second boat 534 between the delivery position and the loading/unloading position.

A maintenance opening 530c is provided in the second side wall 530b. The maintenance opening 530c is provided on the negative side of the second side wall 530b in the Z-axis direction. The maintenance opening 530c is provided at the same height as the load lock chamber A2. The maintenance opening 530c is provided in a position including a middle position between the first processing container 531 and the second processing container 532 in the Y-axis direction. The maintenance opening 530c is provided between a first exhaust box 541a and a second exhaust box 542a in the Y-axis direction. The maintenance opening 530c is an opening for maintenance of the processing module 530. The maintenance opening 530c is a common opening used when the first processing container 531, the second processing container 532, the first boat 533, and the second boat 534 are loaded and unloaded to and from the processing module 530. For this reason, the maintenance opening 530c has a size that allows the first processing container 531, the second processing container 532, the first boat 533, and the second boat 534 to pass therethrough.

For example, the maintenance opening 530c is used when the first processing container 531 is unloaded from the interior of the processing module 530 in order to replace the first processing container 531 due to damage or to clean the first processing container 531. For example, the maintenance opening 530c is used when the second processing container 532 is unloaded from the interior of the processing module 530 in order to replace the second processing container 532 due to damage or to clean the second processing container 532. For example, the maintenance opening 530c is used when the first boat 533 (or the second boat 534) is unloaded from the interior of the processing module 530 in order to replace the first boat 533 (or the second boat 534) due to damage or to clean the first boat 533 (or the second boat 534).

The maintenance door 537 rotates horizontally to open and close the maintenance opening 530c. The maintenance door 537 has a hinge 537a and a door body 537b. The hinge 537a connects the second side wall 530b to the door body 537b. The hinge 537a is provided, for example, on the negative side in the Y-axis direction. The door body 537b may be horizontally rotatable via the hinge 537a with respect to the second side wall 530b. When the door body 537b is opened, the first processing container 531, the second processing container 532, the first boat 533, and the second boat 534 can be loaded and unloaded via the maintenance opening 530c. In FIG. 16, the door body 537b in an open state is shown by a solid line, the door body 537b in a closed state is shown by a dashed line, and the trajectory of a front end of the door body 537b when the door body 537b is opened or closed is shown by a dotted line.

The clean unit 538 is attached to the door body 537b. The clean unit 538 is configured to circulate clean air in the load lock chamber A2. The clean air is, for example, an inert gas. The clean air supplied to the load lock chamber A2 is exhausted from the interior of the load lock chamber A2 by an exhauster (not shown) installed on the first side wall 530a facing the clean unit 538 and is resupplied from the clean unit 538 into the load lock chamber A2.

The exhaust unit 540 has the first exhaust box 541a, a first exhaust pipe 541b, a first pressure control valve 541c, the second exhaust box 542a, a second exhaust pipe 542b, and a second pressure control valve 542c.

The first exhaust box 541a is disposed adjacent to the second side wall 530b on the positive side of the processing module 530 in the Y-axis direction. The first exhaust pipe 541b connects an exhaust port 531a of the first processing container 531 to a vacuum pump (not shown). The first exhaust pipe 541b has a portion between one end and the other end accommodated inside the first exhaust box 541a. The first pressure control valve 541c is provided inside the first exhaust box 541a. The first pressure control valve 541c is interposed in the middle of the first exhaust pipe 541b. The first pressure control valve 541c controls pressure inside the first processing container 531 to a desired pressure.

The second exhaust box 542a is disposed adjacent to the second side wall 530b on the negative side of the processing module 530 in the Y-axis direction. The second exhaust box 542a is disposed at intervals in the Y-axis direction with respect to the first exhaust box 541a. The first exhaust box 541a and the second exhaust box 542a may be disposed so as to be symmetrical with respect to a virtual line L that is equidistant from the center of the first processing container 531 and the center of the second processing container 532. An area between the first exhaust box 541a and the second exhaust box 542a is a maintenance area in which the maintenance opening 530c is exposed. The second exhaust pipe 542b connects an exhaust port 532a of the second processing container 532 to a vacuum pump (not shown). The second exhaust pipe 542b has a portion between one end and the other end accommodated inside the second exhaust box 542a. The second pressure control valve 542c is provided inside the second exhaust box 542a. The second pressure control valve 542c is interposed in the middle of the second exhaust pipe 542b. The second pressure control valve 542c controls pressure inside the second processing container 532 to a desired pressure.

The gas supply unit 550 includes a first supply box 551a, a first supply unit 551b, first supply pipes 551c and 551d, and first supply valves 551e and 551f.

The first supply box 551a is disposed adjacent to the first exhaust box 541a on the positive side in the X-axis direction. The first supply unit 551b is accommodated inside the first supply box 551a. The first supply pipes 551c and 551d connect the first supply unit 551b to nozzles (not shown) that supply process gases into the first processing container 531. The first supply valve 551e is interposed in the first supply pipe 551c. The first supply valve 551f is interposed in the first supply pipe 551d. Mass flow controllers (not shown) may be interposed in the first supply pipe 551c and the first supply pipe 551d. The first supply unit 551b supplies the process gases into the first processing container 531 through the first supply pipes 551c and 551d.

The gas supply unit 550 has a second supply box 552a, a second supply unit (not shown), second supply pipes (not shown), and second supply valves (not shown).

The second supply box 552a is disposed adjacent to the positive side of the second exhaust box 542a in the X-axis direction. The second supply unit, the second supply pipes, and the second supply valves may be configured similarly to the first supply unit 551b, the first supply pipes 551c and 551d, and the first supply valves 551e and 551f.

As described above, according to the fifth embodiment, the substrate processing apparatus 500 includes the processing chamber A1, the load lock chamber A2, the first driving mechanism 535, and the second driving mechanism 536. The first processing container 531 and the second processing container 532 are disposed in the processing chamber A1. In the first processing container 531, processing is collectively performed on the multiple substrates W held by the first boat 533 in a shelf-like shape. In the second processing container 532, processing is collectively performed on the multiple substrates W held by the second boat 534 in a shelf-like shape. The load lock chamber A2 is located below the processing chamber A1 and has an interior communicating with the processing chamber A1. The first driving mechanism 535 moves the first boat 533 up and down and horizontally. The second driving mechanism 536 moves the second boat 534 up and down and horizontally. In this case, the same effect as in the first embodiment is obtained.

According to the fifth embodiment, the first boat 533 and the second boat 534 can be moved to the same delivery position by the first driving mechanism 535 and the second driving mechanism 536. In this case, a mechanism for moving the substrate transfer device 523 in the Y-axis direction is not required. As a result, the length of the processing module 530 in the Y-axis direction can be shortened. In addition, the stroke of the substrate transfer device 523 can be shortened. Thereby, the transfer time of the substrates W by the substrate transfer device 523 can be shortened.

According to the present disclosure in some embodiments, it is possible to reduce the difference in thermal history between substrates.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing apparatus, comprising:
a first processing chamber configured to collectively perform a first processing on a plurality of substrates held by a substrate holder in a shelf-like shape;
a load lock chamber located below the first processing chamber and having an interior communicating with an inside of the first processing chamber; and
a driving mechanism configured to move the substrate holder up and down and horizontally.

2. The substrate processing apparatus of claim 1, wherein the driving mechanism is configured to move the substrate holder up and down between the first processing chamber and the load lock chamber.

3. The substrate processing apparatus of claim 1, wherein the driving mechanism is configured to move the substrate holder horizontally inside the load lock chamber.

4. The substrate processing apparatus of claim 1, wherein the driving mechanism is configured to move the substrate holder horizontally inside the first processing chamber.

5. The substrate processing apparatus of claim 1, wherein the load lock chamber is configured to be capable of being depressurized.

6. The substrate processing apparatus of claim 1, wherein the driving mechanism is configured to move the substrate holder between a processing position at which the first processing is performed and a transfer position at which the substrates are loaded to or unloaded from the substrate holder with the respect to the substrate holder, and
wherein the processing position is different from the transfer position in a horizontal direction.

7. The substrate processing apparatus of claim 1, wherein the driving mechanism includes an articulated arm configured to move the substrate holder up and down and horizontally.

8. The substrate processing apparatus of claim 1, wherein the driving mechanism includes:
an elevation driving mechanism configured to move the substrate holder up and down; and
a horizontal driving mechanism configured to move the substrate holder horizontally.

9. The substrate processing apparatus of claim 1, further comprising a second processing chamber located above the load lock chamber and at a lateral side of the first processing chamber and configured to communicate with an inside of the load lock chamber,
wherein the second processing chamber is configured to be capable of accommodating at least a part of the substrate holder.

10. The substrate processing apparatus of claim 2, further comprising a second processing chamber located above the load lock chamber and at a lateral side of the first processing chamber and configured to communicate with an inside of the load lock chamber,
wherein the second processing chamber is configured to be capable of accommodating at least a part of the substrate holder.

11. The substrate processing apparatus of claim 3, further comprising a second processing chamber located above the load lock chamber and at a lateral side of the first processing chamber and configured to communicate with an inside of the load lock chamber,
wherein the second processing chamber is configured to be capable of accommodating at least a part of the substrate holder.

12. The substrate processing apparatus of claim 4, further comprising a second processing chamber located above the load lock chamber and at a lateral side of the first processing chamber and configured to communicate with an inside of the load lock chamber,
wherein the second processing chamber is configured to be capable of accommodating at least a part of the substrate holder.

13. The substrate processing apparatus of claim 5, further comprising a second processing chamber located above the load lock chamber and at a lateral side of the first processing chamber and configured to communicate with an inside of the load lock chamber,
wherein the second processing chamber is configured to be capable of accommodating at least a part of the substrate holder.

14. The substrate processing apparatus of claim 6, further comprising a second processing chamber located above the load lock chamber and at a lateral side of the first processing chamber and configured to communicate with an inside of the load lock chamber,
wherein the second processing chamber is configured to be capable of accommodating at least a part of the substrate holder.

15. The substrate processing apparatus of claim 7, further comprising a second processing chamber located above the load lock chamber and at a lateral side of the first processing chamber and configured to communicate with an inside of the load lock chamber,
wherein the second processing chamber is configured to be capable of accommodating at least a part of the substrate holder.

16. The substrate processing apparatus of claim 8, further comprising a second processing chamber located above the load lock chamber and at a lateral side of the first processing chamber and configured to communicate with an inside of the load lock chamber,
wherein the second processing chamber is configured to be capable of accommodating at least a part of the substrate holder.

17. The substrate processing apparatus of claim 9, wherein the second processing chamber is configured to be capable of accommodating a part of the substrate holder.

18. The substrate processing apparatus of claim 9, wherein the second processing chamber is configured to be capable of accommodating an entirety of the substrate holder.

19. A substrate processing method, comprising:
moving a substrate holder holding a plurality of substrates in a shelf-like shape to a processing position;
collectively performing processing on the plurality of substrates held by the substrate holder at the processing position;
after the performing the processing, moving the substrate holder to an unloading position immediately below the processing position;
moving the substrate holder located at the unloading position to a transfer position shifted in a horizontal direction from the unloading position; and
taking the plurality of substrates held by the substrate holder at the transfer position out of the substrate holder.
